(19) United States
(12) Patent Application Publication
(10) Pub. No.: US 2014/0264528 A1
(43) Pub. Date: Sep. 18, 2014

(54) NON-VOLATILE MEMORY STRUCTURE

(71) Applicant: MACRONIX INTERNATIONAL CO., LTD., Hsin-Chu City (TW)

(72) Inventors: TAO YUAN LIN, TAIPEI CITY (TW); CHEN HAN CHOU, TAINAN CITY (TW); I CHEN YANG, CHANGHUA COUNTY (TW); YAO WEN CHANG, HSINCHU COUNTY (TW); TAO CHENG LU, HSINCHU CITY (TW)

(73) Assignee: MACRONIX International Co., Ltd., Hsin-Chu City (TW)

(21) Appl. No.: 13/886,011

(22) Filed: May 2, 2013

Related U.S. Application Data
(60) Provisional application No. 61/776,880, filed on Mar. 12, 2013.

(51) Int. Cl. H01L 29/788; H01L 29/66

(52) U.S. Cl. CPC H01L 29/788; H01L 29/66825
USPC 257/315; 438/264

(57) ABSTRACT

A non-volatile memory structure includes a source and a drain. The memory structure includes a substrate and a dielectric layer on the substrate. The memory structure further has a gate, which can be a floating gate, on the dielectric layer. A recess is on the drain side and nearest to the bottom corner of the dielectric layer. The recess is configured to reduce the electric field density around the bottom corner nearest to the drain in order to reduce the damage on the dielectric layer when the memory is under a bias.

### CROSS-REFERENCE TO RELATED APPLICATION

This application claims the priority benefit of U.S. provisional application Ser. No. 61/776,880, filed on Mar. 12, 2013. The entirety of the above-mentioned patent application is hereby incorporated by reference herein and made a part of this specification.

### FIELD OF THE INVENTION

The present invention relates in general to a non-volatile memory structure.

### BACKGROUND

Endurance of a non-volatile memory continues to be a challenge. A threshold voltage window closure, which is the threshold voltage difference between the programming state and erasing state, is a measurement utilized to gauge the endurance of a non-volatile memory structure. If the value of threshold voltage window closure is too small, the non-volatile memory is considered to be degraded. The principal source side degradation is believed to be the decay of the tunneling layer's integrity. Some efforts are made for improving the integrity, which include the changing of material for tunneling layer or optimizing the growth process. These efforts have helped to some degree, but have not been fully effective solution.

### SUMMARY OF THE INVENTION

The main aspect of the present invention addresses that there is another source causing degradation in which electric charges to be read into or out from the floating gate are trapped by defective sites during programming or erasing. With more defective sites, performance of the non-volatile memory decays faster. The tunneling layer, usually a dielectric material film under the floating gate of the flash memory, is on the path for high energy charges (hot carriers) to pass through (e.g., Fowler-Nordheim tunneling or direct tunneling and etc.). Due to its location on the path, the tunneling layer is most vulnerable to the damage, which caused from the hot carriers. The defective sites generated by the hot carrier damage are mainly distributed in the dielectric film or on the bottom surface of the dielectric film over the buried channel. Another major distribution may be seen on the dielectric film's top surface, which is adjacent to the floating gate bottom region. A main factor for having such defective sites is believed to be the high electric field density around the region where the drain side of non-volatile memory cell and tunneling layer meet.

In accordance with the invention, a non-volatile memory structure formed on a substrate is provided with a recess at the drain side. The recess is formed adjacently to the dielectric layer such that the electric field density at the dielectric layer bottom corner (referred to herein as a corner electric field density) nearest to the drain side can be reduced. In particular embodiments of the invention, the corner electric field density on the drain side is equal or lower than the corner electric field density on the source side.

In some particular embodiments, the recessed drain structure can also reduce the corner electric field density to be no greater than 1.3 times of the electric field density on the space between the bottom corners.

The recess can be designed to be at least 100 A (angstrom) deep. In particular embodiments, the depth is 200 A.

The recess can be made from an etching or oxidation process. In particular embodiments, a dry etching is utilized to sculpture the top surface of the substrate. In some particular embodiments, thermal oxidation is utilized to form an oxide layer in the drain, and thereafter the oxide is removed in order to form a recessive drain structure.

### BRIEF DESCRIPTION OF THE DRAWINGS

The invention will be described according to the appended drawings in which:

FIG. 1 illustrates a non-volatile memory structure according to one embodiment.

FIG. 2 illustrates a non-volatile memory structure according to one embodiment.

FIGS. 3A-3B depict electric field density distribution according to one embodiment.

FIG. 4 illustrates a non-volatile memory cell with an adjustable corner angle according to one embodiment.

FIGS. 5A-5B depict a method to form a recessed drain according to one embodiment.

FIGS. 6A-6C depict a method to form a recessed drain according to one embodiment.

### DETAILED DESCRIPTION OF THE INVENTION

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be thorough and complete, and will fully convey the scope of the invention to those skilled in the art.

FIG. 1 illustrates a non-volatile memory cell 10. The non-volatile memory is programmable, which means the memory function in the cell can be programmed or erased. In some particular embodiments, it can be a flash memory, an EPROM, or an EEPROM. The cell 10 includes a substrate 100, and a dielectric layer 101 on the substrate. The top surface of the substrate 100 is separated into at least two topographically distinguishable portions; a first portion 1001, and a second portion 1002. In order to distinguish the first and second portion, a high magnification instrument (e.g., a scanning electron microscope, a transmission electron microscope and etc) can be used to observe or measure the difference. The first portion 1001 is under the dielectric layer 101 and the second portion 1002 is substantially adjacent to the bottom corner 1010 of the dielectric layer 101. The surface level of the first portion 1001 is higher than the surface level of the second portion 1002. A conductive layer 102 is on the dielectric layer 101. The conductive layer 102 can be the gate layer or floating gate of the cell 10 in some embodiments. The dielectric layer 101 can also be called a tunneling layer of the memory call 10, and is configured as a barrier to the injection of hot carriers from the substrate 100 into the conductive layer 102. The dielectric layer 101 is also configured as a barrier to the injection of trapped charges in the conductive layer 102 into the substrate 100. The conductive layer 102 can be a floating gate of the memory cell 10 and functions as a storage space to accommodate trapped charges. The trapped charges may be released into the substrate 100 during erasing. The first portion 1001 provides the channel to the carriers to move under the dielectric layer 101. The second portion 1002 is configured as the drain side of the memory cell 10.

FIG. 2 depicts a non-volatile memory cell 10 with an illustrative drain dopant profile 205. Besides the overlapped region 201, which is under the dielectric layer 101, the drain has a recessive top surface 1002 which is lower than the first portion 1001 surface level. In accordance with the invention, the recessed drain 20 can reduce the electric field density at the bottom corner 1010 of the dielectric 101 on the drain side when there is an electric potential difference between the conductive layer 102 and the drain 20. The depth of the recessive top surface 1002 is measured from the surface level of the surface 1001 to the bottom of the recessed drain 20. In some particular embodiments, the depth is between 150 and 200 A.

FIG. 3A illustrates the electric field density distribution of one embodiment when the depth of the recessed drain is 200 A during an erasing operation of the memory. The electric potential difference between the conductive layer 102 and the drain 20 is −10V. FIG. 3B is a chart that demonstrates the electric field density distribution of FIG. 3A along the interface between the dielectric layer 101 and the substrate 100. The X-axis is along a direction from the source side to the drain side from negative to positive. The Y-axis represents the measured electric field density on the top surface of the dielectric layer 101. Apparently, the corner electric field density on the drain side is lower than the corner electric field density on the source side. The depth of the recess can also be designed to be greater than 200 A. In some embodiments, the depth of the recess is between 150 and 200 A.

In additional to the depth, the profile of the recessed drain can be adjusted according to the requirement. As illustrated in FIG. 4, the angle θ of the recess corner can be approximately near 90 degrees, which means the side wall 202 of the recess is substantially coplanar with the side wall 1015 of the dielectric layer 101. The side wall 202 can also be designed as a sloped surface. In some particular embodiments, the angle θ is between 80 and 90 degrees. In some particular embodiments, the angle 0 is between 75 and 90 degrees.

The recessed drain structure can reduce the difference between the electric field density on the space between the bottom corners of the dielectric layer 101 and the corner electric field density. In some particular embodiments, the corner electric field density does not exceed 1.3 times that of the electric field density on the space between the bottom corners. In some particular embodiments, the corner electric field density does not exceed 1.15 times that of the electric field density on the space between the bottom corners. The depth of the recess and the angle of recess corner are the major key knobs to adjust the corner electric field density.

One of the methods of forming the recess as shown in FIG. 4 is illustrated in FIGS. 5A-5B. A non-volatile memory thin film stack 15 includes a first dielectric layer 101, a first gate 102, a second dielectric layer 103, and a second gate 104. The first gate 102 is the floating gate and the second gate is the control gate. The first dielectric layer 101 is also called the tunneling layer. The memory stack 15 forms on the substrate 100. A first doped region 20 can be formed in the substrate 100 and located adjacently to the bottom corner 1010 of the first dielectric layer 101. The profile of the doped region 20 may encroach into a region 1015 under the first dielectric layer 101 after a thermal process. A photolithography step is introduced to mask other areas and expose the first doped region 20, and followed by an etching step that is introduced to sculpture the top surface of the drain side in order to form a recessed first doped region 20 as shown in FIG. 5B. The etching step is preferred to be an anisotropic etching, which mainly removes the top surface of the substrate 100 without damaging the sidewall of the stack 15. The first doped region 20 can be also formed after the etching step. In some particular embodiments, the first doped region 20 can be the drain of the non-volatile memory thin film stack 15.

Another method of forming the recess as shown in FIG. 4 can be illustrated in FIGS. 6A-6C. A non-volatile memory film stack 15 with a predetermined dimension forms on the substrate 100. An oxidation process is introduced to oxidize only the top surface of the substrate 100 on the first doped region 20 to form an oxide layer 150 as shown in FIG. 6B. A selective etching step is introduced to remove only the oxide formed in the first doped region 20 in order to generate a recess as shown in FIG. 6C. In some particular embodiments, the first doped region 20 can be the drain of the non-volatile memory thin film stack 15.

The methods and features of this invention have been sufficiently described in the above examples and descriptions. It should be understood that any modifications or changes without departing from the spirit of the invention are intended to be covered in the protection scope of the invention.

What is claimed is:

1. A non-volatile memory structure with a source and a drain, comprising:
a substrate;
a dielectric layer on the substrate;
a conductive layer on the dielectric layer; and
a recess on the drain side and nearest to the bottom corner of the dielectric layer.

2. The non-volatile memory structure of claim 1, wherein the dielectric layer is a tunneling layer and the conductive layer is a floating gate.

3. The non-volatile memory structure of claim 1, wherein the depth of the recess is between 100 and 200 A.

4. The non-volatile memory structure of claim 1, wherein the depth of the recess is between 150 and 200 A.

5. The non-volatile memory structure of claim 1, wherein the sidewall of the recess is coplanar with the sidewall of the dielectric layer.

6. The non-volatile memory structure of claim 1, wherein the angle of the recess corner is between 75 and 90 degrees.

7. The non-volatile memory structure of claim 1, wherein the angle of the recess corner is between 80 and 90 degrees.

8. A non-volatile memory cell with a floating gate and drain, in which the cell comprises:
a dielectric tunneling layer under the floating gate, wherein the dielectric tunneling layer is configured to provide a barrier for hot carriers moving in or out of the floating gate; and
a recess on the drain which is adjacent to the bottom corner of the dielectric tunneling layer, wherein the recess is configured to reduce the electric field density around the bottom corner of the dielectric tunneling layer when there is an electric potential difference between the floating gate and the drain.

9. The non-volatile memory cell of claim 8, wherein the depth of the recess is between 150 and 200 A.

10. The non-volatile memory cell of claim 8, wherein the sidewall of the recess is coplanar with the sidewall of the dielectric tunneling layer.

11. The non-volatile memory cell of claim 8, wherein the angle of the recess corner is between 75 and 90 degrees.

12. A method of manufacturing a non-volatile memory structure, comprising:
forming a thin film stack on a substrate, wherein the thin film stack comprises a dielectric layer on the substrate, and a conductive layer configured as a charge storage on the dielectric layer;
forming a first doped region in the substrate; and
forming a recess in the first doped region adjacently to the bottom corner of the dielectric layer.

13. The method of claim 12, wherein forming the recess in the first doped region further comprises an etching step.

14. The method of claim 12, wherein forming the recess in the first doped region further comprises an oxidation step to form an oxide layer.

15. The method of claim 14 further comprising a selective etching step to remove the oxide in the first doped region.
